(19) United States
(12) Patent Application Publication
(10) Pub. No.: US 2026/0231782 A1
(43) Pub. Date: Aug. 6, 2026

(54) DIGITAL SIGNAL ISOLATOR DEVICE

(71) Applicant: TEXAS INSTRUMENTS INCORPORATED, DALLAS, TX (US)

(72) Inventors: Kumar Anurag SHRIVASTAVA, BANGALORE (IN); Arvind GUPTA, NEW DELHI (IN); Gregory OSTROWICKI, DALLAS, TX (US); Vijaylaxmi KHANOLKAR, PUNE (IN); Kashyap Jayendra BAROT, GUJARAT (IN)

(21) Appl. No.: 19/039,378

(22) Filed: Jan. 28, 2025

(51) Int. Cl. H10W 70/40; H03K 5/125

(52) U.S. Cl. CPC H10W 70/421; H03K 5/125; H10W 70/465

(57) ABSTRACT

One example includes a digital signal isolator device. The device includes a transmitter circuit configured to receive a first signal and to provide a first current in response to the first signal and a receiver circuit configured to receive a second current and to generate a second signal in response to the first current. The device also includes a leadframe comprising a transformer. The transformer can include a first portion of the leadframe arranged as a primary of the transformer and a second portion of the leadframe arranged as a secondary of the transformer. The transmitter circuit can be configured to provide the first current on the first portion of the leadframe to inductively generate the second current in the second portion of the leadframe in response to the first current.

### TECHNICAL FIELD

This description relates generally to communications devices, and more particularly to a digital signal isolator device.

### BACKGROUND

Integrated circuit (IC) packages have long been implemented in computer devices for providing increasingly compact circuits in computer products. For some circuit applications, isolated signal transfer may be required between different IC circuits. Isolated signal transfer can be based on providing signal coupling between a transmitter circuit and a receiver circuit without conductive coupling. A typical isolated signal device can include an optical transmitter and an optical receiver. As an example, a digital electric signal can be converted to an optical signal that is transmitted from the optical transmitter, which is received by a closely-coupled optical receiver (e.g., photodiode) that converts the optical signal back to the digital electric signal. Other types of isolation devices can be implemented, but optical isolation devices are typically used as a low-cost option for applications that implement isolated digital signal transfer.

### SUMMARY

One example includes a digital signal isolator device. The device includes a transmitter circuit configured to receive a first signal and to provide a first current in response to the first signal and a receiver circuit configured to receive a second current and to generate a second signal in response to the first current. The device also includes a leadframe comprising a transformer. The transformer can include a first portion of the leadframe arranged as a primary of the transformer and a second portion of the leadframe arranged as a secondary of the transformer. The transmitter circuit can be configured to provide the first current on the first portion of the leadframe to inductively generate the second current in the second portion of the leadframe in response to the first current.

Another example includes method for providing signal isolation. The method includes receiving a first signal at a transmitter circuit conductively coupled to a first portion of a leadframe and providing a first current from the transmitter circuit in response to the first signal. The first current can be provided on the first portion of the leadframe. The leadframe can further include a second portion that is inductively coupled to the first portion, such that a second current is inductively generated in the second portion of the leadframe in response to the first current. The method also includes receiving the second current at a receiver circuit that is conductively coupled to the second portion of the leadframe, and providing a second signal from the receiver circuit in response to the second current.

Another example includes a digital signal isolator device package. The device package includes a transmitter circuit configured to receive a first signal and to provide a first current in response to the first signal and a receiver circuit configured to receive a second current and to generate a second signal in response to the first current. The device package also includes a leadframe including a transformer. The transformer includes a first portion of the leadframe comprising at least one first loop arranged as a primary of the transformer and a second portion of the leadframe comprising at least one second loop arranged as a secondary of the transformer. The transmitter circuit can be configured to provide the first current on the at least one first loop to inductively generate the second current in the at least one second loop in response to the first current. The device package further includes an outer package that substantially surrounds the transmitter circuit, the receiver circuit, and the leadframe.

### BRIEF DESCRIPTION OF THE DRAWINGS

FIG. 1 is an example block diagram of a digital signal isolator device.

FIGS. 2A and 2B are an example of a digital signal isolator device.

FIGS. 3A and 3B are example diagrams of current flow and magnetic field signal transfer in a digital signal isolator device.

FIG. 4 is an example of a digital signal isolator device package.

FIG. 5 is another example of a digital signal isolator device.

FIG. 6 is another example of a digital signal isolator device.

FIGS. 7A, 7B, and 7C, are another example of a digital signal isolator device.

FIGS. 8A, 8B, and 8C are another example of a digital signal isolator device.

FIG. 9 is an example a method for transmitting a signal.

### DETAILED DESCRIPTION

This description relates generally to communications devices, and more particularly to a digital signal isolator device. The digital signal isolator device described herein implements inductive isolated signal transfer via a transformer that is formed by the leadframe of the device package. For example, the leadframe can be fabricated to include a first portion and a second portion, with each of the portions including at least one loop. Thus, the loop(s) of the first portion of the leadframe can correspond to a primary of the transformer and the loop(s) of the second portion of the leadframe can correspond to a secondary of the transformer. As described herein, the terms “primary” and “secondary” refer to conductive coils/loops of a transformer that are inductively coupled to each other to provide transformation of current and magnetic field. Therefore, “primary/secondary” can refer to “primary/secondary coil”, “primary/secondary winding”, “primary/secondary loops”, or any of a variety of other terms to describe the structure of inductively coupled conductors of a transformer.

The first and second portions can each include a die that corresponds, respectively, to a transmitter device and a receiver device. Therefore, an input signal provided to the digital signal isolator device can be converted by the transmitter device to a current that is provided on the loop(s) of the first portion of the leadframe to inductively provide a second current in the loop(s) of the second portion of the leadframe based on an inductive coupling of the loop(s) of each of the portions of the leadframe. Therefore, the second current can be provided to the receiver device, and the receiver device can convert the second current into an output signal that can be provided from the digital signal isolator device.

As an example, the leadframe can be formed as planar with respect to the first and second portions. Therefore, for a multi-loop portion of the leadframe, the loops can be formed as concentric with respect to each other. At least one of the loops in the concentric arrangement can be coupled to a next loop via a bond wire that extends in a manner that is offset from the planar arrangement. As another example, the offset bond wires can cooperate with the leadframe portion to form a solenoid. Accordingly, the transformer formed by the portions of the leadframe can be formed in a variety of ways.

As described herein, the first and second portions of the leadframe of the digital signal isolator device can be conductively isolated with respect to each other. Therefore, signal isolation can be accomplished based on the inductive signal transfer between the loop(s) of the respective portions of the leadframe. By including the transformer as part of the leadframe, the transformer can be fabricated in a very simplistic and inexpensive manner. As a result, the digital signal isolator device can be implemented as a low-cost alternative to inductive isolators that implement a transformer-on-silicon (SAX) arrangement in an isolator device, and thus as a low-cost alternative to optical isolator devices.

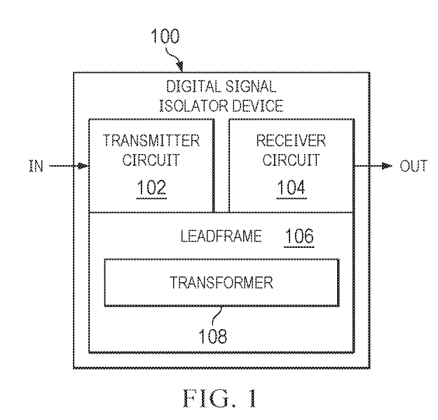

FIG. 1 is an example block diagram of a digital signal isolator device 100. The digital signal isolator device 100 can be fabricated in any of a variety of ways. The digital signal isolator device 100 can be implemented to provide digital signal isolation between an input signal IN and an output signal OUT, such that the input signal IN and the output signal OUT are conductively isolated with respect to each other. Therefore, the digital signal isolator device 100 can be implemented in any of a variety of applications in which signal isolation may be required or may optimize circuit operation.

The digital signal isolator device 100 includes a transmitter circuit 102 and a receiver circuit 104. The transmitter circuit 102 and the receiver circuit 104 can be formed as semiconductor dies in an integrated circuit (IC) fabrication process. The transmitter circuit 102 and the receiver circuit 104 can be coupled to a leadframe 106, such as a via a die-attach film (DAF). In the example of FIG. 1, the leadframe 106 includes a transformer 108 that is configured to provide signal isolation between the input signal IN and the output signal OUT. As an example, the leadframe 106 can be fabricated as any of a variety of different types of leadframes, such as for a leaded leadframe package (e.g., for a small outline integrated circuit (SOIC) package), a leadless leadframe package (e.g., quad flat no-lead (QFN)), or a multi-layer substrate package (e.g., ball grid array (BGA) or land grid array (LGA) pacakages).

As described herein, the leadframe 106 can be formed into conductively isolated portions that each include one or more loops that can correspond, respectively, to a primary and a secondary of the transformer 108. The loops of the primary and secondary of the transformer 108 can thus be formed from a typical leadframe material (e.g., copper or aluminum). As described herein, by forming the transformer 108 as or as part of the leadframe 106, the transformer 108 can be fabricated in a very simplistic and inexpensive manner. As a result, the digital signal isolator device can be implemented as a low-cost alternative to other types of inductive isolators or optical isolators.

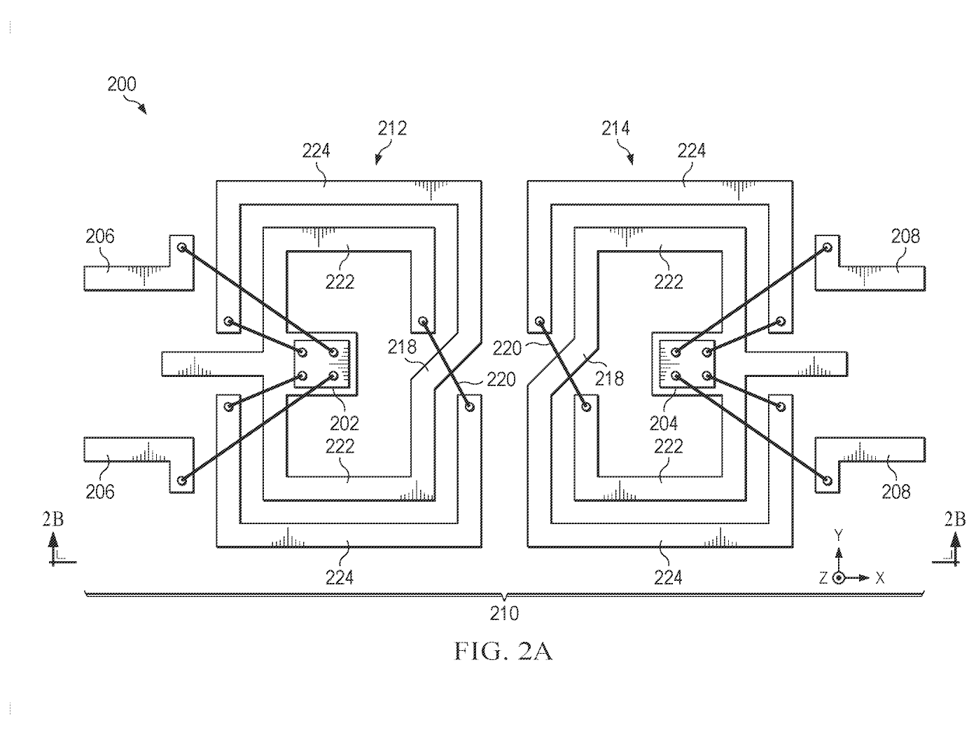

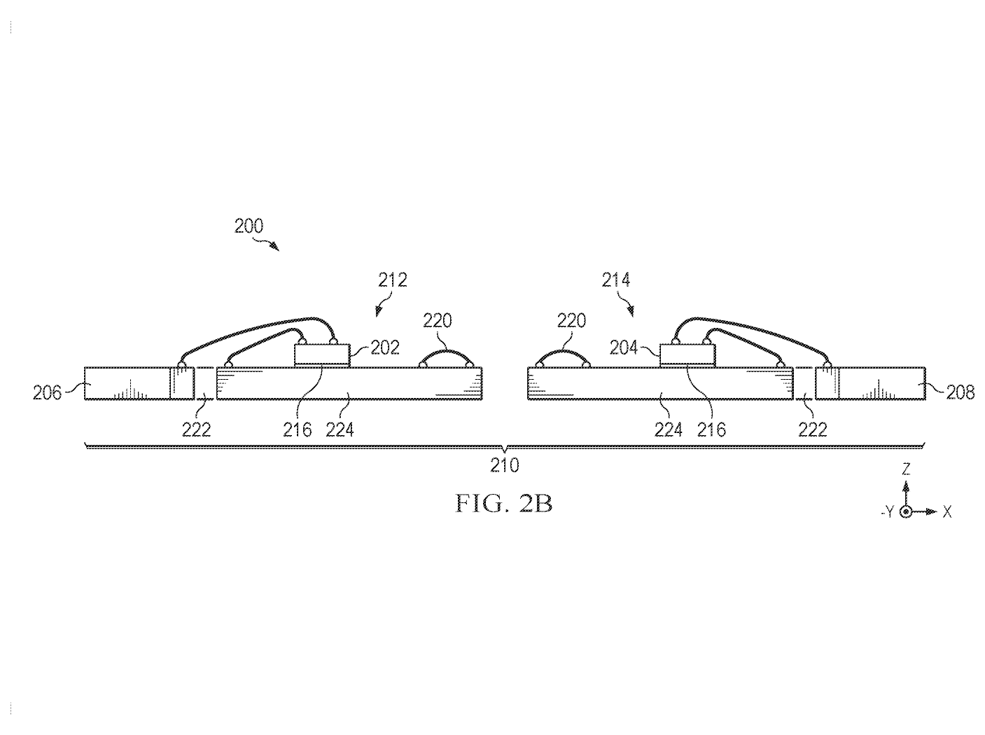

FIGS. 2A and 2B demonstrate an example of a digital signal isolator device 200. The digital signal isolator device 200 can correspond to the digital signal isolator device 100 in the example of FIG. 1. Therefore, reference is to be made to the example of FIG. 1 in the following example of FIG. 2. The example of FIG. 2A demonstrates a plan view of the digital signal isolator device 200, while the example of FIG. 2B demonstrates a side view of the digital signal isolator device 200, based on Cartesian coordinates.

The digital signal isolator device 200 includes a transmitter circuit 202 and a receiver circuit 204. The transmitter and receiver circuits 202 and 204 can be fabricated as IC dies. As described above, the transmitter circuit 202 can receive an input signal IN and can generate a current in response to the input signal IN. In the example of FIG. 2, the input signal IN can be provided via signal contacts 206. As also described above, the receiver circuit 204 can receive a current and can generate the output signal OUT in response to the current. In the example of FIG. 2, the output signal OUT can be provided on signal contacts 208. While the discussion herein describes a unidirectional communication between a “transmitter circuit” and a “receiver circuit”, the circuits 202 and 204 can each be configured instead as transceivers, such as to provide bidirectional communication between the respective IC circuit dies 202 and 204 via signals provided to either of the signal contacts 206 and 208.

The digital signal isolator device 200 also includes a lead frame 210 that includes a first portion 212 on which the transmitter circuit 202 is mounted, and a second portion 214 on which the receiver circuit 204 is mounted, both via a DAF 216. The portions 212 and 214 of the lead frame 210 are demonstrated as being provided in a coplanar and laterally offset manner. Additionally, the portions 212 and 214 of the lead frame 210 are conductively isolated with respect to each other. Instead, the first portion 212 and the second portion 214 are demonstrated in the example of FIG. 2 as including loops for a current path. Therefore, the first and second portions 212 and 214 of the leadframe 210 can be inductively coupled in response to a current provided from the transmitter circuit 202.

The first and second portions 212 and 214 of the lead frame 210 are each demonstrated in the example of FIG. 2 as including a first loop 222 and a second loop 224 in a planar concentric arrangement. The loops 222 and 224 are electrically coupled to each other via a lead frame extension 218 and a bond wire 220. The lead frame extension 218 can be part of the planar arrangement of the lead frame 210, such that the lead frame extension 218 can be fabricated to be structurally integral with the first and second loops 222 and 224. The bond wire 220 can extend in an offset manner from the planar arrangement of the lead frame 210, such that the bond wire 220 can extend over and cross the lead frame extension 218.

Each of the transmitter and receiver circuits 202 and 204 are conductively coupled to the respective portions 212 and 214 to provide a current path through the loops 222 and 224. As an example, in response to the input signal IN, the transmitter circuit 202 can generate the current with a high voltage (e.g., less than approximately 400mV RMS) to provide sufficient magnetic field via the loops 222 and 224 of the first portion 212 to inductively generate a current in the loops 222 and 224 of the second portion 214.

The current through the loops 222 and 224 of the first portion 212 can be modulated to correspond to the input signal IN, such that the current through the loops 222 and 224 of the second portion 214 can likewise be modulated to correspond to the input signal IN. The second current can thus be provided through the receiver circuit 204, such that the receiver circuit 204 can generate the output signal OUT. The output signal OUT can thus correspond to an isolated version of the input signal IN. Accordingly, the digital signal isolator device 200 can implement isolated signal transfer between the input signal IN and the output signal OUT based on the inductive coupling of the transformer formed by the loops 222 and 224 in each of the first and second portions 212 and 214.

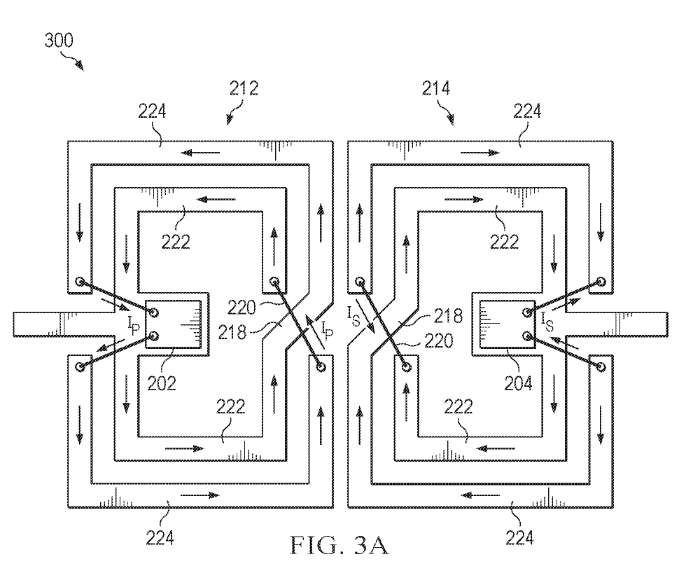

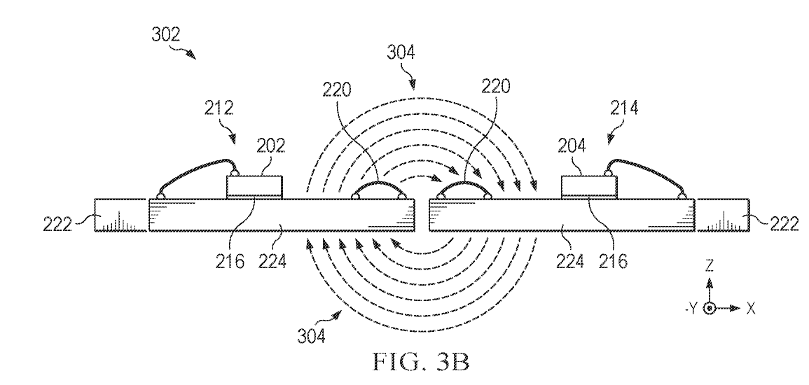

FIGS. 3A and 3B are an example diagram 300 of current flow and an example diagram 302 of magnetic field signal transfer in the digital signal isolator device 200. The diagram 300 demonstrates an example of the direction of flow of a primary current I_{P} that is provided from the transmitter circuit 202 through the loops 222 and 224 of the first portion 212 of the leadframe 210 in response to the input signal IN. The diagram 302 demonstrates the magnetic field, illustrated in the example of FIG. 3B as dotted directional arrows at 304, that is generated in response to the primary current I_{P}.

The magnetic field 304 is thus provided as magnetic flux through the loops 222 and 224 of the second portion 214 of the lead frame 210. Accordingly, as demonstrated in the diagram 300, the magnetic field 304 induces a secondary current I_{S} in the loops 222 and 224 of the second portion 214 of the lead frame 210. The secondary current I_{S} is thus provided through the receiver circuit 204, such that the receiver circuit 204 can generate the output signal OUT in response.

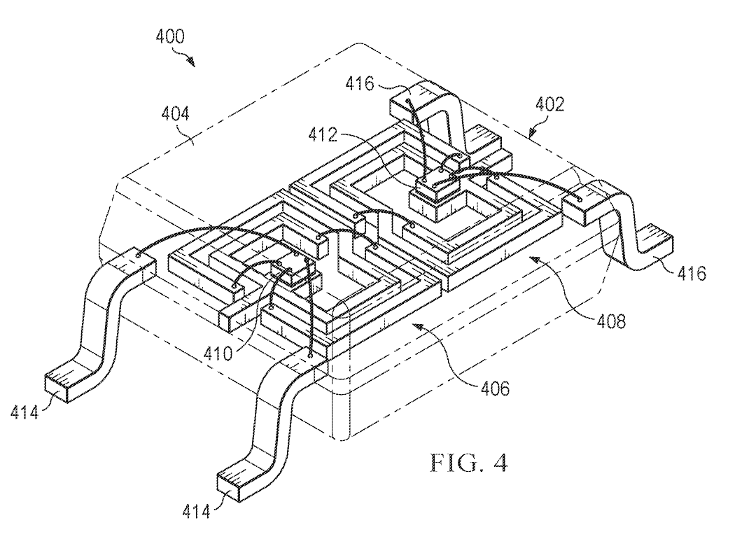

FIG. 4 is an example of a digital signal isolator device package 400. The digital signal isolator device package 400 includes a digital signal isolator device 402 enclosed within a package 404 (e.g., plastic case), demonstrated as transparent to facilitate viewing the digital signal isolator device 402. As an example, the digital signal isolator device 402 can correspond to the digital signal isolator device 200 in the examples of FIGS. 2 and 3. Conductively isolated portions 406 and 408 of a leadframe with the respective transmitter and receiver circuits 410 and 412 can be disposed on a packaging material surface in a coplanar and laterally offset arrangement within the package 404. As demonstrated in the example of FIG. 4, signal contacts 414 and 416 can be provided exterior to the package 404 to facilitate receiving the input signal IN and providing the output signal OUT. A potting material (not shown) can be provided to fill the empty spaces in the interior of the package 404. Accordingly, the digital signal isolator device package 400 is demonstrated as a standalone circuit device for providing isolated signal transfer between the signal contacts 414 and 416.

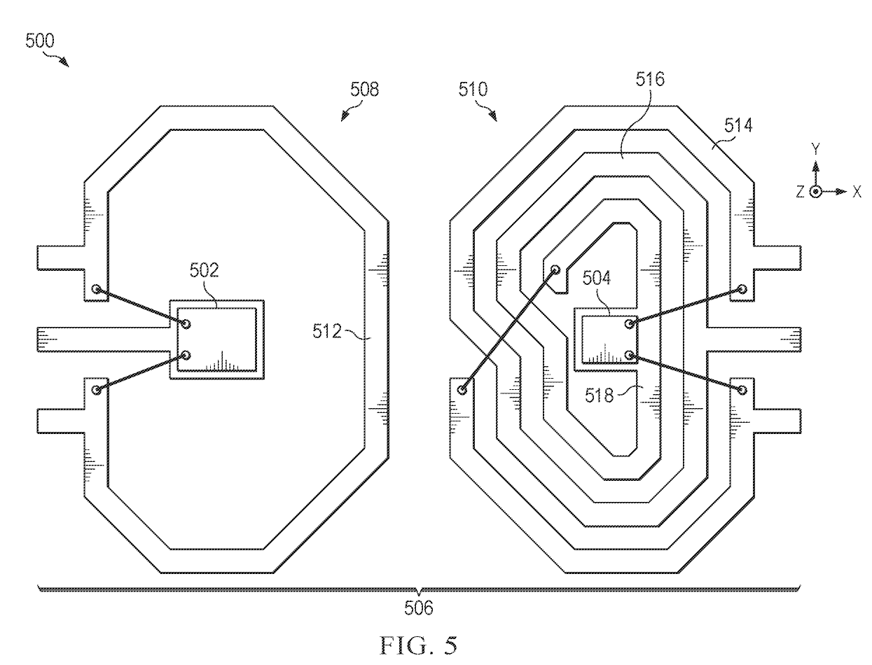

A digital signal isolator device described herein is not structurally or functionally limited to the digital signal isolator device 200 demonstrated in the examples of FIGS. 2 and 3. FIG. 5 is another example of a digital signal isolator device 500.

The digital signal isolator device 500 includes a transmitter circuit 502 and a receiver circuit 504. The digital signal isolator device 500 also includes a leadframe 506 that includes a first portion 508 on which the transmitter circuit 502 is mounted, and a second portion 510 on which the receiver circuit 504 is mounted. The portions 508 and 510 of the leadframe 506 are demonstrated as being provided in a coplanar and laterally offset manner, similar to as described above with respect to the digital signal isolator device 200. Additionally, the portions 508 and 510 of the leadframe 506 are conductively isolated with respect to each other.

As opposed to the digital signal isolator device 200, the digital signal isolator device 500 is demonstrated as the first portion 508 including a single loop 512 and the second portion 510 including three loops 514, 516, and 518. Therefore, the first and second portions 508 and 510 have an unequal quantity of loops. The disparity in loop quantity between the portions 508 and 510 of the leadframe 506 can provide for a voltage step-up or step-down between the primary and secondary of the transformer formed by the portions 508 and 510 of the leadframe 506. Therefore, the quantity of loops of a given digital signal isolator device described herein is not limited to being equal between the primary and secondary, and not limited to the 1:3 ratio demonstrated in the example of FIG. 5, but can instead be any number of loops respectively between the primary and secondary of the transformer formed by the portions 508 and 510 of the leadframe 506.

Additionally, the portions 508 and 510 of the leadframe 506 are demonstrated in the example of FIG. 5 as being less orthogonal with respect to the bends of the loops 512, 514, 516, and 518 in the plane of the portions 508 and 510. Such an arrangement in the example of FIG. 5 demonstrates that the manner of forming the loops of a given digital signal isolator device is not limited to right angle bends, but can instead be shaped in a variety of different ways, such as to satisfy dimensional or spatial considerations. Furthermore, portions of the loops are not limited to being linear, and/or can have multiple small angular bends along the lengths. FIG. 6 is another example of a digital signal isolator device 600 that is arranged similar to the digital signal isolator device 500, but with non-linear (e.g., having multiple small angle bends) portions of the loops. Accordingly, the digital signal isolator devices described herein can be formed and structured in any of a variety of ways.

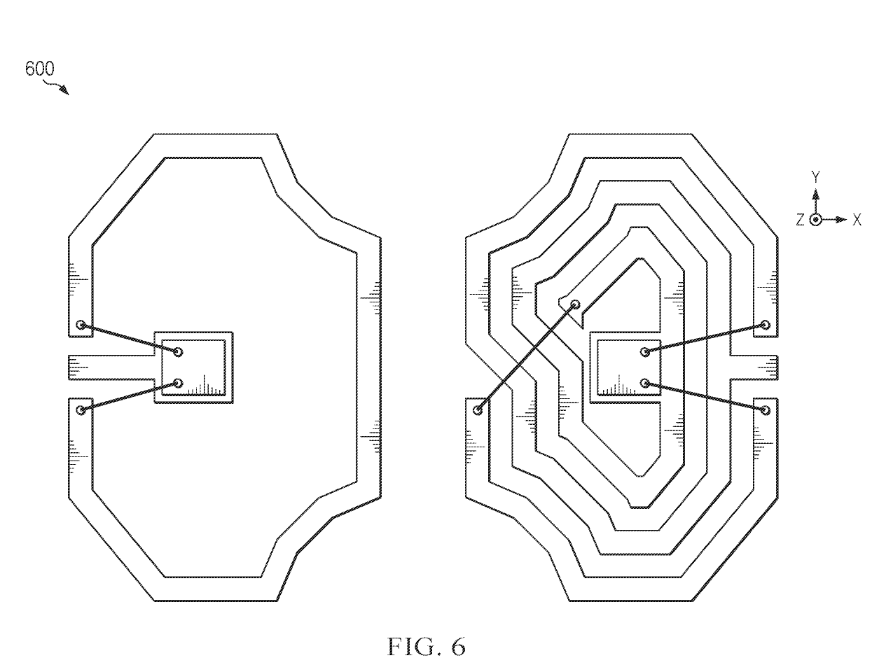

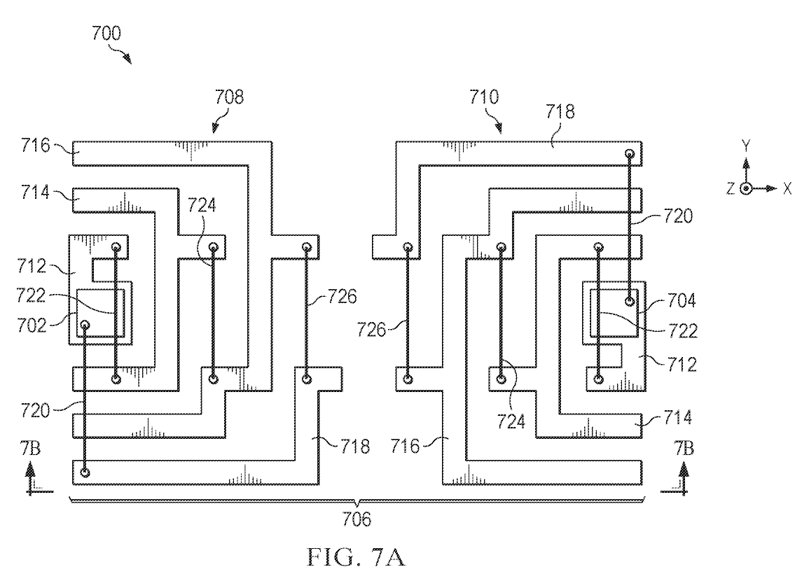

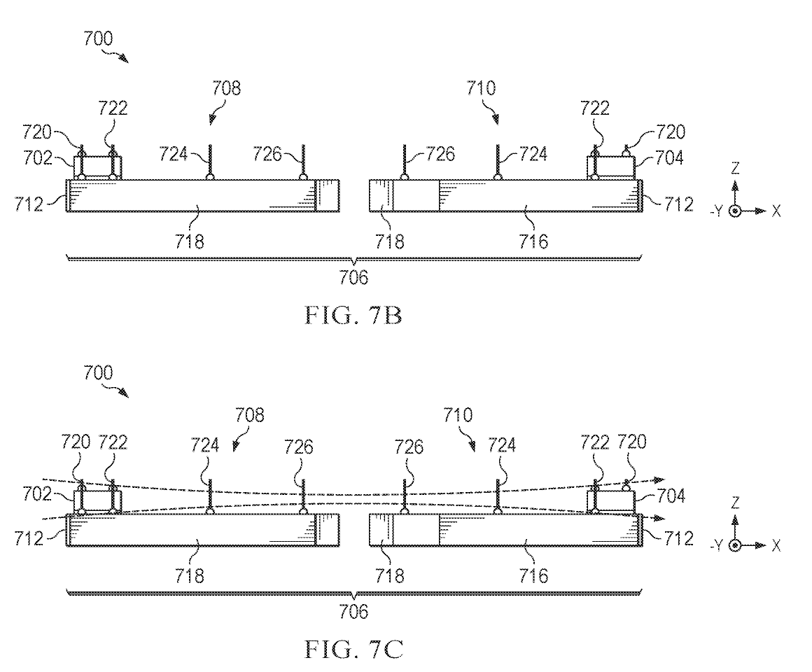

FIGS. 7A, 7B, and 7C are another example of a digital signal isolator device 700. The example of FIG. 7A demonstrates a plan view of the digital signal isolator device 700, while the examples of FIGS. 7B and 7C demonstrate a side view of the digital signal isolator device 700, based on Cartesian coordinates.

The digital signal isolator device 700 includes a transmitter circuit 702 and a receiver circuit 704. The digital signal isolator device 700 also includes a lead frame 706 that includes a first portion 708 on which the transmitter circuit 702 is mounted, and a second portion 710 on which the receiver circuit 704 is mounted. The portions 708 and 710 of the lead frame 706 are demonstrated as being provided in a coplanar and laterally offset manner, similar to as described above with respect to the digital signal isolator device 200. Additionally, the portions 708 and 710 of the lead frame 706 are conductively isolated with respect to each other.

In the example of FIG. 7A, the portions 708 and 710 of the leadframe 706 include a first portion 712, a second portion 714, a third portion 716, and a fourth portion 718. The digital signal isolator device 700 also includes bond wires that couple the portions to each other and to the transmitter circuit 702 and the receiver circuit 704, respectively. The bond wires can extend orthogonally offset from the coplanar arrangement of the portions 708 and 710 of the leadframe 706.

In the example of FIG. 7, the digital signal isolator device 700 includes a first bond wire 720 that connects the transmitter/receiver circuit 702/704 to the fourth portion 720, a second bond wire 722 that connects the first portion 712 to the second portion 714, a third bond wire 724 that connects the second portion 714 to the third portion 716, and a fourth bond wire 726 that connects the third portion 716 to the fourth portion 718. Therefore, as opposed to the digital signal isolator devices 200, 500, and 600, the digital signal isolator device 700 is demonstrated such that the loops of the primary and secondary of the transformer are partially formed by the bond wires 720, 722, 724, and 726. The bond wires 720, 722, 724, and 726 and the portions 712, 714, 716, and 718 thus collectively form a solenoid arrangement for the respective primary and secondary of the transformer.

The loops of each of the first and second portions 708 and 710 of the leadframe 706 are demonstrated as approximately coaxial with respect to each other. As demonstrated in the example of FIG. 7C, the magnetic field, demonstrated by dotted directional arrows at 730, that is generated by the primary current is thus provided through the solenoids formed by the loops of each of the first and second portions 708 and 710 of the leadframe 706. As a result, the magnetic field 730 generated by the loops of the primary is directed substantially entirely through the loops of the secondary. Accordingly, the digital signal isolator device 700 can provide for potentially more efficient signal isolation relative to the digital signal isolator devices 200, 500, or 600 in which up to approximately 50% of the magnetic field is coupled from the primary to the secondary.

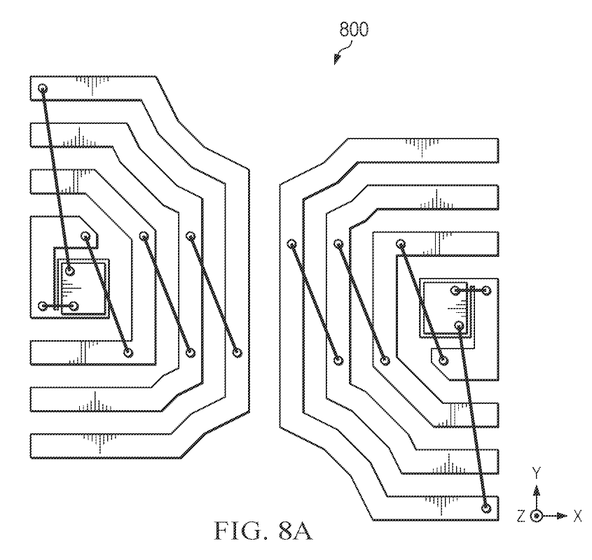

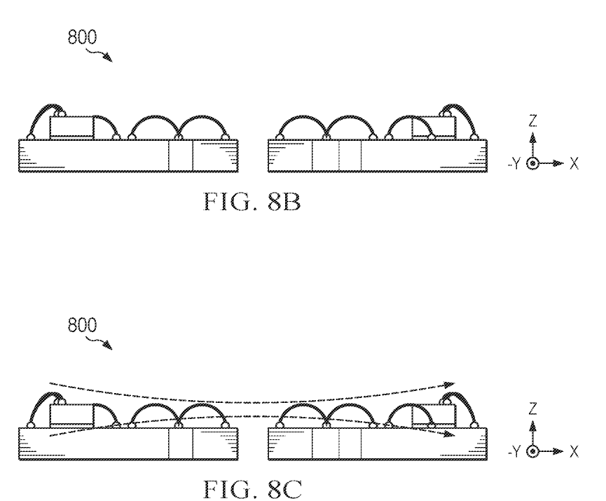

FIGS. 8A, 8B, and 8C are another example of a digital signal isolator device 800. The digital signal isolator device 800 is arranged functionally and structurally similar to the digital signal isolator device 700 in the example of FIG. 7. Therefore, reference is to be made to the example of FIG. 7 with respect to the digital signal isolator device 800. However, similar to as described above in the example of FIG. 6, the digital signal isolator device 800 includes substantially non-linear (e.g., having multiple small angle bends) portions of the leadframe, such as to satisfy spatial or dimensional considerations. In the examples of FIGS. 7 and 8, other portions of the leadframe do not form the loops of the primary and secondary, and can be implemented instead to provide structural and mechanical support during fabrication, such as to support the wire-bonding process. Additionally, the digital signal isolator devices 700 and 800 are not limited to having leadframe portions that are the same, but can instead have structural differences, as well as an unequal quantity of loops, similar to as described above in the examples of FIGS. 5 and 6.

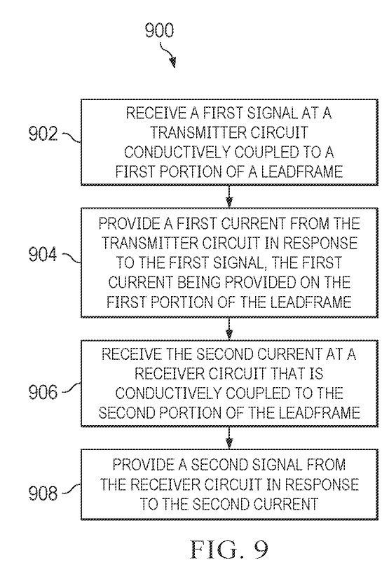

In view of the foregoing structural and functional features described above, a methodology in accordance with various aspects of the present invention will be better appreciated with reference to FIG. 9. While, for purposes of simplicity of explanation, the methodology of FIGS. 9 is shown and described as executing serially, it is to be understood and appreciated that the present invention is not limited by the illustrated order, as some aspects could, in accordance with the present invention, occur in different orders and/or concurrently with other aspects from that shown and described herein. Moreover, not all illustrated features may be required to implement a methodology in accordance with an aspect of the present invention.

FIG. 9 illustrates another example of a method 900 for providing signal isolation. At 902, a first signal (e.g., the input signal IN) is received at a transmitter circuit (e.g., the transmitter circuit 102) conductively coupled to a first portion (e.g., the first portion 212) of a lead frame (e.g., the lead frame 106). At 904, a first current (e.g., the primary current I_{P}) is provided from the transmitter circuit in response to the first signal. The first current can be provided on the first portion of the lead frame. The lead frame can further include a second portion (e.g., the second portion 214) that is inductively coupled to the first portion, such that a second current (e.g., the secondary current I_{S}) is inductively generated in the second portion of the lead frame in response to the first current. At 906, the second current is received at a receiver circuit (e.g., the receiver circuit 104) that is conductively coupled to the second portion of the lead frame. At 908, a second signal (e.g., the output signal OUT) is provided from the receiver circuit in response to the second current.

In this description, the term "couple" may cover connections, communications, or signal paths that enable a functional relationship consistent with this description. For example, if device A generates a signal to control device B to perform an action, then: (a) in a first example, device A is directly coupled to device B; or (b) in a second example, device A is indirectly coupled to device B through intervening component C if intervening component C does not substantially alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

Modifications are possible in the described embodiments, and other embodiments are possible, within the scope of the claims.

What is claimed is:

1. A digital signal isolator device comprising:
a transmitter circuit configured to receive a first signal and to provide a first current in response to the first signal;
a receiver circuit configured to receive a second current and to generate a second signal in response to the first current; and
a leadframe comprising a transformer, the transformer comprising a first portion of the leadframe arranged as a primary of the transformer and a second portion of the leadframe arranged as a secondary of the transformer, the transmitter circuit being configured to provide the first current on the first portion of the leadframe to inductively generate the second current in the second portion of the leadframe in response to the first current.

2. The device of claim 1, wherein the first portion of the leadframe comprises at least one first loop corresponding to the primary of the transformer, such that the first current propagates from the transmitter circuit, around through the at least one first loop corresponding to the primary, and back to the transmitter circuit, wherein the second portion of the leadframe comprises at least one second loop corresponding to the secondary of the transformer, such that the second current is induced in response to the first current to propagate from the receiver circuit, around the at least one second loop corresponding to the secondary, and back to the receiver circuit.

3. The device of claim 2, wherein each of the at least one first loop and the at least one second loop are fabricated from a leadframe material.

4. The device of claim 2, wherein the at least one first loop is coplanar and laterally offset with respect to the at least one second loop.

5. The device of claim 2, wherein a portion of each of the at least one first loop is formed from a first bond wire that extends in an orthogonally offset manner from the first portion of the leadframe to form a first solenoid, wherein a portion of each of the at least one second loop is formed from a second bond wire that extends in the orthogonally offset manner from the second portion of the leadframe to form a second solenoid, the first and second solenoids being approximately coaxial.

6. The device of claim 2, wherein the at least one first loop has a quantity of loops that is not equal to a quantity of loops of the at least one second loop.

7. The device of claim 2, wherein the at least one first loop is a first plurality of loops, wherein the at least one second loop is a second plurality of loops, wherein each of the first loops and the second loops are arranged concentrically.

8. The device of claim 7, wherein the first plurality of loops comprises a first loop and a second loop of the first portion of the leadframe, wherein the second plurality of loops comprises a first loop and a second loop of the second portion of the leadframe, wherein the first portion of the leadframe comprises a first extension that conductively couples the first and second loops of the first portion of the leadframe, wherein the second portion of the leadframe comprises a second extension that conductively couples the first and second loops of the second portion of the leadframe.

9. The device of claim 8, wherein the first and second extensions are formed integral with the respective first and second loops of the respective first and second portions of the leadframe.

10. The device of claim 8, wherein the first and second loops of the first portion of the leadframe are conductively coupled via a first bond wire, and wherein the first and second loops of the first portion of the leadframe are conductively coupled via a second bond wire.

11. The device of claim 10, wherein the first and second portions of the leadframe are arranged in a coplanar and laterally offset configuration, wherein the first bond wire crosses the first extension in an orthogonally offset manner from the coplanar configuration, and wherein the second bond wire crosses the second extension in the orthogonally offset manner from the coplanar configuration.

12. The device of claim 1, wherein the first portion of the leadframe and the second portion of the leadframe are conductively isolated with respect to each other.

13. The device of claim 1, further comprising an outer package that substantially surrounds the transmitter circuit, the receiver circuit, and the leadframe.

14. A method for providing signal isolation, the method comprising:
receiving a first signal at a transmitter circuit conductively coupled to a first portion of a leadframe;
providing a first current from the transmitter circuit in response to the first signal, the first current being provided on the first portion of the leadframe, the leadframe further comprising a second portion that is inductively coupled to the first portion, such that a second current is inductively generated in the second portion of the leadframe in response to the first current;
receiving the second current at a receiver circuit that is conductively coupled to the second portion of the leadframe; and
providing a second signal from the receiver circuit in response to the second current.

15. The method of claim 14, wherein providing the first current comprises providing the first current from the transmitter circuit on at least one first loop corresponding to the first portion of the leadframe arranged as a primary of a transformer, wherein receiving the second current comprises receiving the second current from at least one second loop corresponding to the second portion of the leadframe arranged as a secondary of the transformer, the secondary being inductively coupled to the primary.

16. The method of claim 15, wherein a portion of each of the at least one first loop is formed from a bond wire that extends in an orthogonally offset manner from the first portion of the leadframe to form a first solenoid, wherein a portion of each of the at least one second loop is formed from a bond wire that extends in the orthogonally offset manner from the second portion of the leadframe to form a second solenoid, the first and second solenoids being approximately coaxial.

17. The method of claim 15, wherein at least one of the at least one first and second loops are arranged as a plurality of concentric loops.

18. The method of claim 15, wherein the at least one first loop comprises a first loop and a second loop of the first portion of the leadframe, wherein the at least one second loop comprises a first loop and a second loop of the second portion of the leadframe, wherein the first portion of the leadframe comprises a first extension that is integral with and conductively couples the first and second loops of the first portion of the leadframe, wherein the second portion of the leadframe comprises a second extension that is integral with and conductively couples the first and second loops of the second portion of the leadframe, wherein the first and second loops of the first portion of the leadframe are conductively coupled via a first bond wire, and wherein the first and second loops of the first portion of the leadframe are conductively coupled via a second bond wire.

19. The method of claim 18, wherein the first and second portions of the leadframe are arranged in a coplanar and laterally offset configuration, wherein the first bond wire crosses the first extension in an orthogonally offset manner from the coplanar configuration, and wherein the second bond wire crosses the second extension in an orthogonally offset manner from the coplanar configuration.

20. A digital signal isolator device package comprising:
a transmitter circuit configured to receive a first signal and to provide a first current in response to the first signal;
a receiver circuit configured to receive a second current and to generate a second signal in response to the first current;
a leadframe comprising a transformer, the transformer comprising a first portion of the leadframe comprising at least one first loop arranged as a primary of the transformer and a second portion of the leadframe comprising at least one second loop arranged as a secondary of the transformer, the transmitter circuit being configured to provide the first current on the at least one first loop to inductively generate the second current in the at least one second loop in response to the first current; and
an outer package that substantially surrounds the transmitter circuit, the receiver circuit, and the leadframe.

21. The package of claim 20, wherein at least one of the at least one first and second loops are arranged as a plurality of concentric loops.

22. The package of claim 20, wherein a portion of each of the at least one first loop is formed from a bond wire that extends in an orthogonally offset manner from the first portion of the leadframe to form a first solenoid, wherein a portion of each of the at least one second loop is formed from a bond wire that extends in the orthogonally offset manner from the second portion of the leadframe to form a second solenoid, the first and second solenoids being approximately coaxial.

23. The package of claim 20, wherein the first plurality of loops comprises a first loop and a second loop of the first portion of the leadframe, wherein the second plurality of loops comprises a first loop and a second loop of the second portion of the leadframe, wherein the first portion of the leadframe comprises a first extension that is integral with and conductively couples the first and second loops of the first portion of the leadframe, wherein the second portion of the leadframe comprises a second extension that is integral with and conductively couples the first and second loops of the second portion of the leadframe.

24. The package of claim 23, wherein the first and second loops of the first portion of the leadframe are conductively coupled via a first bond wire, and wherein the first and second loops of the first portion of the leadframe are conductively coupled via a second bond wire.

25. The package of claim 24, wherein the first and second portions of the leadframe are arranged in a coplanar and laterally offset configuration, wherein the first bond wire crosses the first extension in an orthogonally offset manner from the coplanar configuration, and wherein the second bond wire crosses the second extension in the orthogonally offset manner from the coplanar configuration.
